(19) United States
(12) Patent Application Publication
(10) Pub. No.: US 2025/0089542 A1
(43) Pub. Date: Mar. 13, 2025

(54) DISPLAY SUBSTRATE AND DISPLAY APPARATUS

(71) Applicants: Mianyang BOE Optoelectronics Technology Co., Ltd., Mianyang, Sichuan (CN); BOE Technology Group Co., Ltd., Beijing (CN)

(72) Inventors: Chenglong Hu, Beijing (CN); Huan Zhao, Beijing (CN)

(73) Assignees: Mianyang BOE Optoelectronics Technology Co., Ltd., Mianyang, Sichuan (CN); BOE Technology Group Co., Ltd., Beijing (CN)

(21) Appl. No.: 18/576,051

(22) PCT Filed: Jan. 18, 2023
(86) PCT No.: PCT/CN2023/072906

§ 371 Date: Jan. 2, 2024

(51) Int. Cl. H10K 59/80; H10K 59/122

(52) U.S. Cl. CPC H10K 59/8792; H10K 59/122; H10K 59/873

(57) ABSTRACT

A display substrate is provided. The display substrate includes a base substrate; a pixel definition layer defining a plurality of subpixel apertures, a respective subpixel aperture of the plurality of subpixel apertures configured to receive at least a portion of a light emitting layer; and a support layer on a side of the pixel definition layer away from the base substrate. The support layer includes a plurality of support structures. A respective support structure of the plurality of support structures at least partially surrounds the respective subpixel aperture.

### TECHNICAL FIELD

The present invention relates to display technology, more particularly, to a display substrate and a display apparatus.

### BACKGROUND

Organic light emitting diode (OLED) display apparatuses are self-emissive devices, and do not require backlights. OLED display apparatuses also provide more vivid colors and a larger color gamut as compared to the conventional liquid crystal display (LCD) apparatuses. Further, OLED display apparatuses can be made more flexible, thinner, and lighter than a typical LCD apparatus. An OLED display apparatus typically includes an anode, an organic layer including a light emitting layer, and a cathode. OLEDs can be either a bottom-emission type OLED or a top-emission type OLED.

### SUMMARY

In one aspect, the present disclosure provides a display substrate, comprising a base substrate; a pixel definition layer defining a plurality of subpixel apertures, a respective subpixel aperture of the plurality of subpixel apertures configured to receive at least a portion of a light emitting layer; and a support layer on a side of the pixel definition layer away from the base substrate; wherein the support layer comprises a plurality of support structures; and a respective support structure of the plurality of support structures at least partially surrounds the respective subpixel aperture.

Optionally, the pixel definition layer comprises a plurality of pixel definition rings; and an orthographic projection of a respective pixel definition ring of the plurality of pixel definition rings on the base substrate covers an orthographic projection of the respective support structure on the base substrate.

Optionally, the plurality of pixel definition rings are spaced apart from each other.

Optionally, the respective support structure is in direct contact with the respective pixel definition ring.

Optionally, in a cross-section perpendicular to a surface of the base substrate and intersecting two adjacent support structures of the plurality of support structure, the respective support structure has a first average width, the respective pixel definition ring has a second average width; and the second average width is greater than the first average width.

Optionally, the respective pixel definition ring has a first side and a second side substantially opposite to each other, a third side connecting the first side and the second side, and a fourth side connecting the first side and the second side; the second side is on a side of the first side distal to the base substrate; the fourth side is on a side of the third side away from a center of the respective pixel definition ring; the third side has a first slope angle with respect to the first side; the fourth side has a second slope angle with respect to the first side; the first slope angle is in a range of 15 degrees to 45 degrees; and the second slope angle is in a range of 15 degrees to 45 degrees.

Optionally, the pixel definition layer comprises a black material; and the support layer and the pixel definition layer comprise different materials.

Optionally, in at least a region of the display substrate, a portion of the pixel definition layer is a unitary structure defining the plurality of subpixel apertures.

Optionally, the plurality of support structures in the region and outside the region are made of a same material; and the unitary structure in the region and a plurality of pixel definition rings outside the region are made of a same material.

Optionally, the plurality of support structures are spaced apart from each other at least partially by an encapsulating layer.

Optionally, the display substrate comprises a first region and a second region; wherein the display substrate in the first region has a first visible light transmission rate, and in the second region has a second visible light transmission rate; and the first visible light transmission rate is higher than the second visible light transmission rate.

Optionally, in the first region, the pixel definition layer comprises a plurality of pixel definition rings, and the support layer comprises a plurality of first support structures; in the first region, an orthographic projection of a respective pixel definition ring of the plurality of pixel definition rings on the base substrate at least partially overlaps with an orthographic projection of a respective first support structure of the plurality of first support structures on the base substrate; in the second region, a portion of the pixel definition layer is a unitary structure continuously extending in the region, except that the pixel definition layer does not extend into the plurality of subpixel apertures; in the second region, the support layer comprises a plurality of second support structures; and in the second region, an orthographic projection of the portion of the pixel definition layer on the base substrate at least partially overlaps with an orthographic projection of the respective second support structure on the base substrate.

Optionally, the respective support structure is a closed ring.

Optionally, the respective support structure is an open ring.

Optionally, the respective support structure and the respective pixel definition ring are parts of a unitary structure.

Optionally, the pixel definition layer comprises a black material; and the support layer comprises the black material.

In another aspect, the present disclosure provides a display apparatus, comprising the display substrate described herein or fabricated by a method described herein, and one or more integrated circuits connected to the display substrate.

In another aspect, the present disclosure provides a display substrate, comprising a base substrate; a pixel definition layer defining a plurality of subpixel apertures, a respective subpixel aperture of the plurality of subpixel apertures configured to receive at least a portion of a light emitting layer; a support layer on a side of the pixel definition layer away from the base substrate; and an encapsulating layer on a side of the support layer away from the base substrate; wherein the support layer comprises a plurality of support structures; the encapsulating layer comprises a first inorganic encapsulating sub-layer, an organic encapsulating sub-layer on the first inorganic encapsulating sub-layer, and a second inorganic encapsulating sub-layer on a side of the organic encapsulating sub-layer away from the first inorganic encapsulating sub-layer; the organic encapsulating sub-layer has a first thickness in a first sub-region, a second thickness in a second sub-region, and a third thickness in a third sub-region; and the first thickness, the second thickness, and the third thickness are different from each other.

Optionally, the first sub-region is in an inter-subpixel region, is between adjacent support structures of the plurality of support structures; the support layer and the pixel definition layer is absent in the first sub-region; the second sub-region is in a respective subpixel region of a plurality of subpixel regions; the support layer and the pixel definition layer is absent in the second sub-region; the light emitting layer is present in the second sub-region; the third sub-region is in the inter-subpixel region; the respective support structure and the respective pixel definition ring are both present in the third sub-region; and the first thickness is greater than the second thickness, and the second thickness is greater than the third thickness.

Optionally, the organic encapsulating sub-layer has a fourth thickness in a fourth sub-region; the fourth sub-region is a sub-region wherein the respective support structure is absent and the pixel definition layer is present; and the second thickness is greater than the fourth thickness, and the fourth thickness is greater than the third thickness.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of a related display substrate.

FIG. 2 is a schematic diagram illustrating the structure of a related display substrate.

FIG. 3 is a schematic diagram illustrating the structure of a related display substrate.

FIG. 4 is a cross-sectional view along an A-A′ line in FIG. 3.

FIG. 5 is a schematic diagram illustrating the structure of a display substrate in some embodiments according to the present disclosure.

FIG. 6 is a cross-sectional view along a B-B′ line in FIG. 5.

FIG. 7A is a schematic diagram illustrating the structure of a pixel definition layer and a support layer in a display substrate in some embodiments according to the present disclosure.

FIG. 7B is a schematic diagram illustrating the structure of a pixel definition layer in a display substrate in some embodiments according to the present disclosure.

FIG. 7C is a schematic diagram illustrating the structure of a support layer in a display substrate in some embodiments according to the present disclosure.

FIG. 8 is a schematic diagram illustrating the structure of a display substrate in some embodiments according to the present disclosure.

FIG. 9 is a cross-sectional view along a C-C′ line in FIG. 8.

FIG. 10 is a schematic diagram illustrating the structure of a display substrate in some embodiments according to the present disclosure.

FIG. 11 is a schematic diagram illustrating the structure of a pixel definition layer in the display substrate depicted in FIG. 10.

FIG. 12 is a schematic diagram illustrating the structure of a support layer in the display substrate depicted in FIG. 10.

FIG. 13 is a cross-sectional view along a D-D′ line in FIG. 10.

FIG. 14 is a schematic diagram illustrating the structure of a display substrate in some embodiments according to the present disclosure.

FIG. 15 is a schematic diagram illustrating the structure of a first region and a second region of a display substrate in some embodiments according to the present disclosure.

FIG. 16 is a cross-sectional view along a E-E′ line in FIG. 15.

FIG. 17 is a schematic diagram illustrating the structure of a display substrate in some embodiments according to the present disclosure.

FIG. 18 is a cross-sectional view in a display substrate in some embodiments according to the present disclosure.

FIG. 19 is a cross-sectional view in a display substrate in some embodiments according to the present disclosure.

FIG. 20 is a cross-sectional view in a display substrate in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

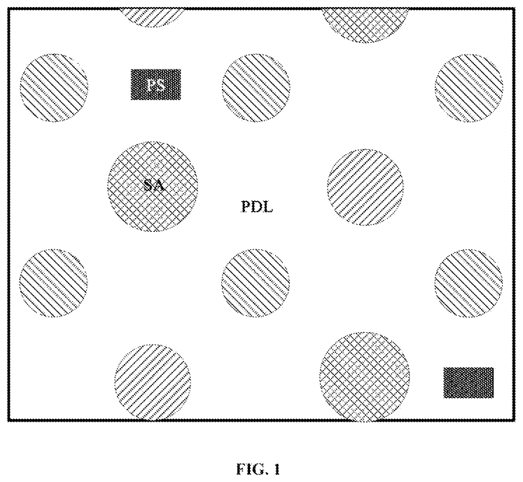

In a related display substrate, a pixel definition layer defines a plurality of subpixel apertures for receiving light emitting materials. FIG. 1 is a schematic diagram illustrating the structure of a related display substrate. Referring to FIG. 1, a pixel definition layer PDL defines a plurality of subpixel apertures SA. A spacer layer PS is then formed on the pixel definition layer PDL. The spacer layer PS may be used for supporting a mask plate. Using one or more mask plates, light emitting materials of different colors may be disposed in the plurality of subpixel apertures SA, respectively.

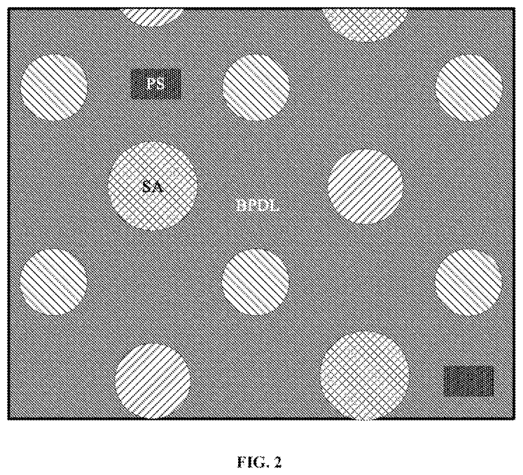

FIG. 2 is a schematic diagram illustrating the structure of a related display substrate. Referring to FIG. 2, in the related display substrate, a black pixel definition layer may be used for defining the plurality of subpixel apertures SA. In particular, a black pixel definition layer is often used in a color-on-encapsulation display substrate, which a color filter is directly formed on the encapsulation layer. As compared to a transparent pixel definition layer which typically has a visible light transmission rate greater than 80%, the black pixel definition layer BPDL has a relatively low light transmission rate, e.g., less than 10%. In regions of the display substrate that requires a relatively higher light transmission rate, the black pixel definition layer has to be partially removed to enhance light transmission.

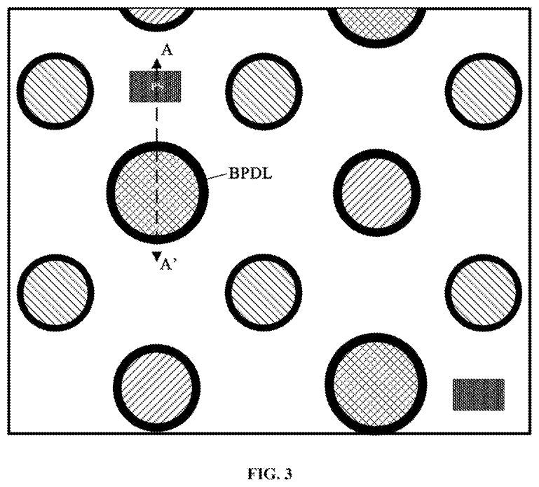

FIG. 3 is a schematic diagram illustrating the structure of a related display substrate. FIG. 4 is a cross-sectional view along an A-A′ line in FIG. 3. FIG. 3 and FIG. 4 depict a related display substrate in which the black pixel definition layer BPDL is partially removed. For example, the black pixel definition layer BPDL is present in only a region surrounding a respective subpixel aperture of the plurality of subpixel apertures. The black pixel definition layer BPDL is absent (e.g., removed) in other regions. Referring to FIG. 4, a spacer layer PS is then formed in the display substrate. The spacer layer PS includes a plurality of spacers in an inter-subpixel region of the display substrate, e.g., in an array. Because the black pixel definition layer PDL is absent in regions where the plurality of spacers are formed, a respective spacer of the plurality of spacers has a first height h1 relative to a base substrate BS of the display substrate smaller than a second height h2 of the black pixel definition layer BPDL relative to the base substrate BS. For example, the first height h1 is 1.2 μm, and the second height h2 is 1.5 μm. Because the first height h1 is smaller than the second height h2, the spacers are not able to support a mask plate. The mask plate inadvertently damages the display substrate by scratching or electrostatic discharge.

Accordingly, the present disclosure provides, inter alia, a display substrate and a display apparatus that substantially obviate one or more of the problems due to limitations and disadvantages of the related art. In one aspect, the present disclosure provides a display substrate. In some embodiments, the display substrate includes a base substrate; a pixel definition layer defining a plurality of subpixel apertures, a respective subpixel aperture of the plurality of subpixel apertures configured to receive at least a portion of a light emitting layer; and a support layer on a side of the pixel definition layer away from the base substrate. Optionally, the support layer comprises a plurality of support structures. Optionally, a respective support structure of the plurality of support structures at least partially surrounds the respective subpixel aperture.

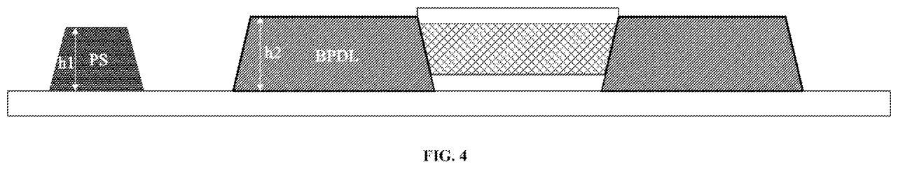

FIG. 5 is a schematic diagram illustrating the structure of a display substrate in some embodiments according to the present disclosure. Referring to FIG. 5, the display panel in some embodiments includes a plurality of subpixel region SR and an inter-subpixel region ISR. As used herein, a subpixel region refers to a light emission region of a subpixel, such as a region corresponding to a pixel electrode in a liquid crystal display, or a region corresponding to a light emissive layer in a light emitting diode display panel. Optionally, a pixel may include a number of separate light emission regions corresponding to a number of subpixels in the pixel. Optionally, the subpixel region is a light emission region of a red color subpixel. Optionally, the subpixel region is a light emission region of a green color subpixel. Optionally, the subpixel region is a light emission region of a blue color subpixel. Optionally, the subpixel region is a light emission region of a white color subpixel. As used herein, an inter-subpixel region refers to a region between adjacent subpixel regions, such as a region corresponding to a black matrix in a liquid crystal display, or a region corresponding a pixel definition layer in a light emitting diode display panel. Optionally, the inter-subpixel region is a region between adjacent subpixel regions in a same pixel. Optionally, the inter-subpixel region is a region between two adjacent subpixel regions from two adjacent pixels. Optionally, the inter-subpixel region is a region between a subpixel region of a red color subpixel and a subpixel region of an adjacent green color subpixel. Optionally, the inter-subpixel region is a region between a subpixel region of a red color subpixel and a subpixel region of an adjacent blue color subpixel. Optionally, the inter-subpixel region is a region between a subpixel region of a green color subpixel and a subpixel region of an adjacent blue color subpixel.

FIG. 6 is a cross-sectional view along a B-B′ line in FIG. 5. Referring to FIG. 6, in some embodiments, the display substrate includes a base substrate BS; an active layer ACT of a respective one of a plurality of thin film transistors TFT on the base substrate BS; a gate insulating layer GI on a side of the active layer ACT away from the base substrate BS; a gate electrode G and a first capacitor electrode Ce1 (both are parts of a first gate metal layer) on a side of the gate insulating layer GI away from the base substrate BS; an insulating layer IN on a side of the gate electrode G and the first capacitor electrode Ce1 away from the gate insulating layer GI; a second capacitor electrode Ce2 (a part of a second gate metal layer) on a side of the insulating layer IN away from the gate insulating layer GI; an inter-layer dielectric layer ILD on a side of the second capacitor electrode Ce2 away from the gate insulating layer GI; a source electrode S and a drain electrode D (parts of a first SD metal layer) on a side of the inter-layer dielectric layer ILD away from the gate insulating layer GI; a passivation layer PVX on a side of the source electrode S and the drain electrode D away from the inter-layer dielectric layer ILD; a first planarization layer PLN1 on a side of the passivation layer PVX away from the inter-layer dielectric layer ILD; a relay electrode RE (part of a second SD metal layer) on a side of the first planarization layer PLN1 away from the passivation layer PVX; a second planarization layer PLN2 on side of the first planarization layer PLN1 away from the passivation layer PVX; a pixel definition layer PDL defining a subpixel aperture and on a side of the second planarization layer PLN2 away from the base substrate BS; and a light emitting element LE at least partially in the subpixel aperture. The light emitting element LE includes an anode AD on a side of the second planarization layer PLN2 away from the first planarization layer PLN1; a light emitting layer EL on a side of the anode AD away from the second planarization layer PLN2; and one or more common layers CL (e.g., including one or more organic material layer such as a hole transport layer and an electron transport layer, and further including a cathode layer) on a side of the light emitting layer EL away from the anode AD. The display substrate in the display area further includes an encapsulating layer EN encapsulating the light emitting element LE, and on a side of the one or more common layers CL away from the base substrate BS.

The encapsulating layer EN in some embodiments includes a first inorganic encapsulating sub-layer CVD1 on a side of the one or more common layers CL away from the base substrate BS, an organic encapsulating sub-layer IJP on a side of the first inorganic encapsulating sub-layer CVD1 away from the base substrate BS, and a second inorganic encapsulating sub-layer CVD2 on a side of the organic encapsulating sub-layer IJP away from the base substrate BS.

The display substrate in some embodiments further includes a support layer SL on a side of the pixel definition layer PDL away from the base substrate BS, and a side of the encapsulating layer EN closer to the base substrate BS. As discussed in further details below, the support layer SL in some embodiments includes a plurality of support structures SPR. In some embodiments, a respective support structure of the plurality of support structures SPR at least partially (e.g., completely) surrounds a respective subpixel aperture.

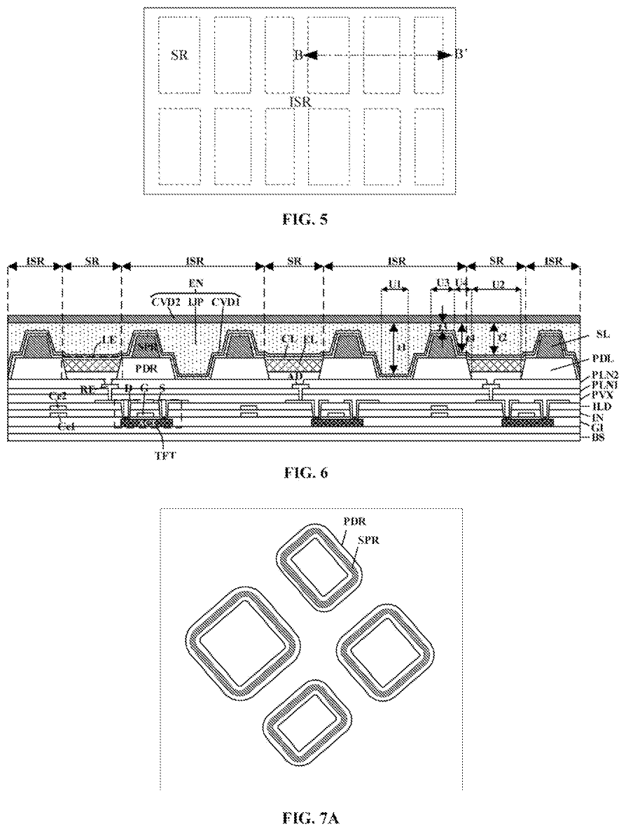

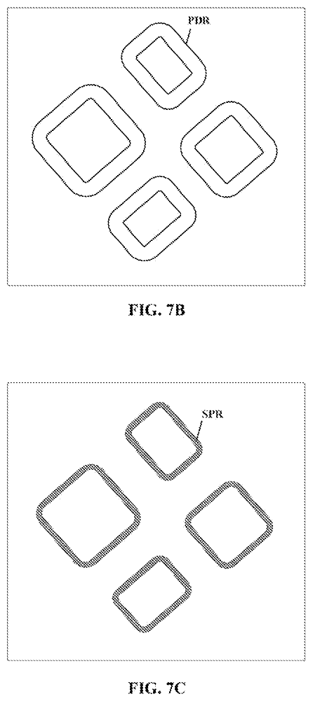

FIG. 7A is a schematic diagram illustrating the structure of a pixel definition layer and a support layer in a display substrate in some embodiments according to the present disclosure. FIG. 7B is a schematic diagram illustrating the structure of a pixel definition layer in a display substrate in some embodiments according to the present disclosure. FIG. 7C is a schematic diagram illustrating the structure of a support layer in a display substrate in some embodiments according to the present disclosure. Referring to FIG. 6, and FIG. 7A to FIG. 7C, the pixel definition layer PDL in some embodiments includes a plurality of pixel definition rings PDR, and the support layer SL in some embodiments includes a plurality of support structures SPR. In some embodiments, an orthographic projection of a respective pixel definition ring of the plurality of pixel definition rings PDR on a base substrate BS at least partially overlaps with an orthographic projection of a respective support structure of the plurality of support structures SPR on the base substrate BS. Optionally, the orthographic projection of the respective pixel definition ring on the base substrate BS covers the orthographic projection of the respective support structure on the base substrate BS. Optionally, the respective support structure is in direct contact with the respective pixel definition ring.

As used herein, the term “ring” or “ring structure” refers to a structure or portion of a structure having a hole there through, including but not limited to a ring or doughnut shape. A ring structure may be essentially round like a doughnut, or may be formed of a square, triangle or another shape with a hole there through. A ring structure does not require that the ring shape be unbroken, and the term is intended to encompass structures that are substantially closed, but that comprise a break or a gap in the ring shape. For example, the term encompasses structures that have a “C” and “U”-shape. A ring structure may consist essentially of a single ring, or it may be a component of a larger structure having additional features, e.g., additional ring structures, or non-ring-shaped features such as corners, points, strings, etc.

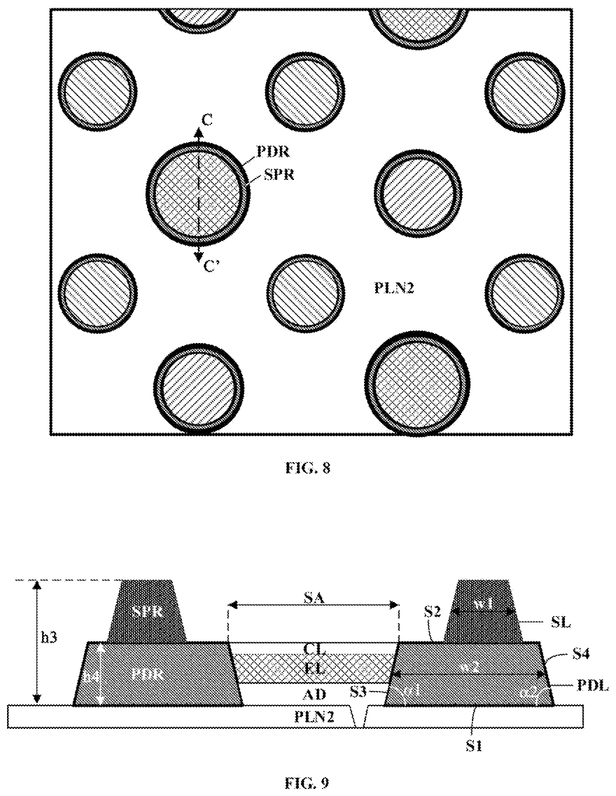

FIG. 8 is a schematic diagram illustrating the structure of a display substrate in some embodiments according to the present disclosure. FIG. 9 is a cross-sectional view along a C-C′ line in FIG. 8. Referring to FIG. 8 and FIG. 9, a respective pixel definition ring of the plurality of pixel definition rings PDR in some embodiments defines a respective subpixel aperture of a plurality of subpixel apertures SA. In some embodiments, the respective pixel definition ring substantially surrounds at least a portion of the light emitting layer EL. As used herein the term “substantially surrounding” refers to surrounding at least 50% (e.g., at least 60%, at least 70%, at least 80%, at least 90%, at least 95%, at least 99%, and 100%) of a perimeter of an area. A respective support structure of the plurality of support structures SPR at least partially (e.g., completely) surrounds the respective subpixel aperture of the plurality of subpixel apertures SA.

Referring to FIG. 8 and FIG. 9, the respective support structure of the plurality of support structures SPR has a third height h3 relative to a base substrate (e.g., the second planarization layer PLN2) of the display substrate. The respective pixel definition ring of the plurality of pixel definition rings PDR has a fourth height h4 relative to the base substrate. As shown in FIG. 9, by having the respective support structure stacked on the respective pixel definition ring, the third height h3 is greater than the fourth height h4. When a mask plate is placed on the respective support structure in the process of depositing, e.g., a light emitting material, the respective support structure spaces apart the mask plate and other components of the display substrate, avoiding damages such as scratching and electrostatic discharge. In one example, the third height h3 is 2.7 μm, and the fourth height h4 is 1.5 μm. In one example, the respective support structure has a thickness in a range of 0.6 μm to 1.2 μm, e.g., 0.6 μm to 0.8 μm, 0.8 μm to 1.0 μm, or 1.0 μm to 1.2 μm.

In some embodiments, the respective pixel definition ring has a first side S1 and a second side S2 substantially opposite to each other, a third side S3 connecting the first side S1 and the second side S2, and a fourth side S4 connecting the first side S1 and the second side S2. The second side S2 is on a side of the first side S1 distal to the base substrate. The fourth side S4 is on a side of the third side S3 away from a center of the respective pixel definition ring. The third side S3 has a first slope angle al with respect to the first side S1. The fourth side S4 has a second slope angle α2 with respect to the first side S1. Optionally, the first slope angle α1 is in a range of 15 degrees to 45 degrees. Optionally, the second slope angle α2 is in a range of 15 degrees to 45 degrees. By having the first slope angle α1 and/or the second slope angle α2 in this range, it can be ensured that a common layer (e.g., a cathode layer or one or more sub-layer of the encapsulating layer EN) deposited on the pixel definition layer PDL would not break or segregate at an edge of the respective pixel definition ring. Two adjacent pixel definition rings of the plurality of pixel definition rings PDR can be spaced apart by a distance depending on a requirement of aperture ratio of the display substrate.

In some embodiments, the respective support structure is on a side of the respective pixel definition ring away from the base substrate. Optionally, the respective support structure is in direct contact with the respective pixel definition ring. The display substrate includes a stacked structure comprising the respective support structure and the respective pixel definition ring.

In some embodiments, in a cross-section perpendicular to a surface of the base substrate (e.g., the second planarization layer PLN2) and intersecting two adjacent support structures of the plurality of support structures SPR, the respective support structure has a shape having a first side closer to the base substrate and a second side on a side of the first side away from the base substrate, the first side having a width greater than the second side. Optionally, the respective support structure in the cross-section has a trapezoidal shape.

In some embodiments, in a cross-section perpendicular to a surface of the base substrate (e.g., the second planarization layer PLN2) and intersecting two adjacent support structures of the plurality of support structures SPR, the respective pixel definition ring has a shape having a third side closer to the base substrate and a fourth side on a side of the third side away from the base substrate, the third side having a width greater than the fourth side. Optionally, the respective pixel definition ring in the cross-section has a trapezoidal shape.

In some embodiments, in a cross-section perpendicular to a surface of the base substrate (e.g., the second planarization layer PLN2) and intersecting two adjacent support structures of the plurality of support structures SPR, the respective support structure has a first average width w1, the respective pixel definition ring has a second average width w2. Optionally, w2 is greater than w1. Optionally, w2 is greater than w1 by at least 10%, e.g., by at least 20%, by at least 30%, by at least 40%, by at least 50%, by at least 60%, by at least 70%, by at least 80%, by at least 90%, by at least 100%, by at least 150%, by at least 200%, by at least 250%, by at least 300%, by at least 350%, by at least 400%, by at least 450%, or by at least 500%. Optionally, w2 is greater than 2 μm.

In some embodiments, the pixel definition layer PDL includes a black material. As used herein, the term “black material” refers to a material having a light transmission rate less than 50% (e.g., less than 40%, less than 30%, less than 20%, less than 10%, or less than 5%) with respect to a visible light wavelength range. In some embodiments, the support layer SL includes a substantially transparent material. As used herein, the term “substantially transparent material” refers to a material having a light transmission rate more than 50% (e.g., more than 60%, more than 70%, more than 80%, more than 90%, or more than 95%) with respect to a visible light wavelength range.

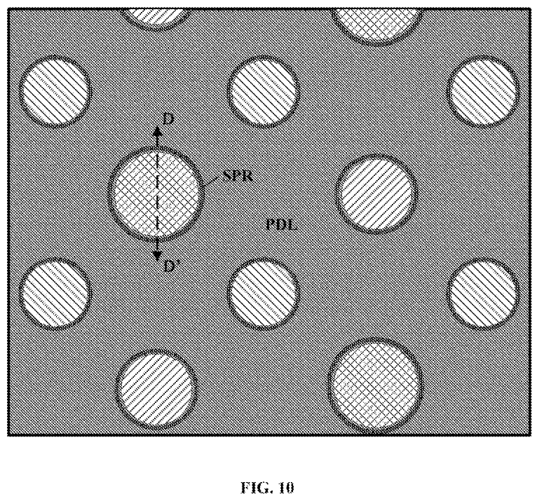

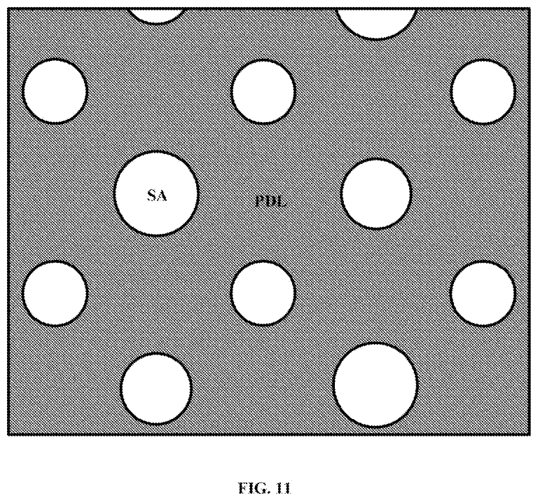

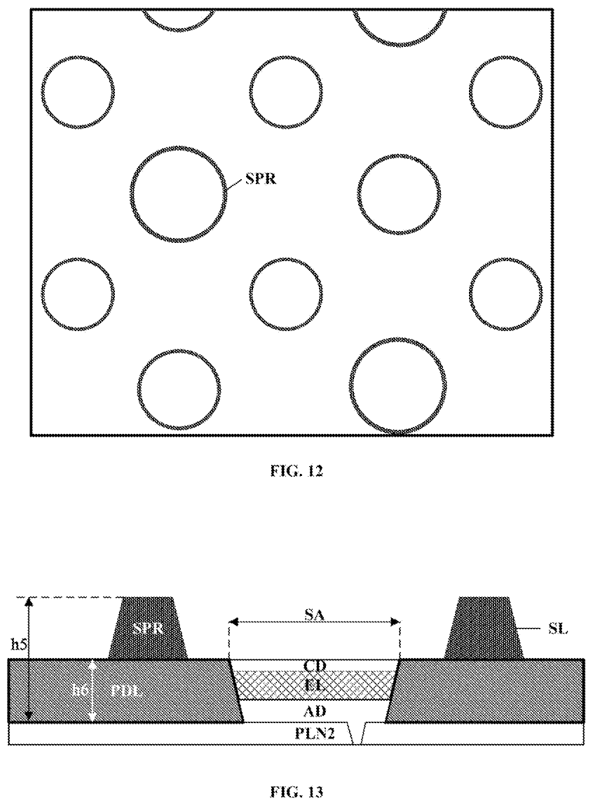

In some embodiments, the pixel definition layer is not partially removed in at least a region of the display substrate. FIG. 10 is a schematic diagram illustrating the structure of a display substrate in some embodiments according to the present disclosure. FIG. 11 is a schematic diagram illustrating the structure of a pixel definition layer in the display substrate depicted in FIG. 10. FIG. 12 is a schematic diagram illustrating the structure of a support layer in the display substrate depicted in FIG. 10. FIG. 13 is a cross-sectional view along a D-D′ line in FIG. 10. Referring to FIG. 10 to FIG. 13, in at least a region of the display substrate, the plurality of pixel definition rings are absent. In at least the region of the display substrate, the pixel definition layer PDL is a unitary structure continuously extending in the region, except that the pixel definition layer PDL does not extend into the plurality of subpixel apertures SA. The pixel definition layer PDL defines the plurality of subpixel apertures SA. A respective support structure of the plurality of support structures SPR at least partially (e.g., completely) surrounds the respective subpixel aperture of the plurality of subpixel apertures SA.

Referring to FIG. 10 to FIG. 13, the respective support structure of the plurality of support structures SPR has a fifth height h5 relative to a base substrate (e.g., the second planarization layer PLN2) of the display substrate. The pixel definition layer PDL has a sixth height h6 relative to the base substrate. As shown in FIG. 13, by having the respective support structure stacked on the pixel definition layer PDL, the fifth height h5 is greater than the sixth height h6. When a mask plate is placed on the respective support structure in the process of depositing, e.g., a light emitting material, the respective support structure spaces apart the mask plate and other components of the display substrate, avoiding damages such as scratching and electrostatic discharge. In one example, the fifth height h5 is 2.7 μm, and the sixth height h6 is 1.5 μm. In one example, the respective support structure has a thickness in a range of 0.6 μm to 1.2 μm, e.g., 0.6 μm to 0.8 μm, 0.8 μm to 1.0 μm, or 1.0 μm to 1.2 μm.

In some embodiments, in a cross-section perpendicular to a surface of the base substrate (e.g., the second planarization layer PLN2) and intersecting two adjacent support structures of the plurality of support structures SPR, the respective support structure has a shape having a first side closer to the base substrate and a second side on a side of the first side away from the base substrate, the first side having a width greater than the second side. Optionally, the respective support structure in the cross-section has a trapezoidal shape.

In some embodiments, the respective support structure is on a side of the pixel definition layer PDL away from the base substrate. Optionally, the respective support structure is in direct contact with the pixel definition layer PDL. In some embodiments, the pixel definition layer PDL includes a black material. In some embodiments, the support layer SL includes a substantially transparent material.

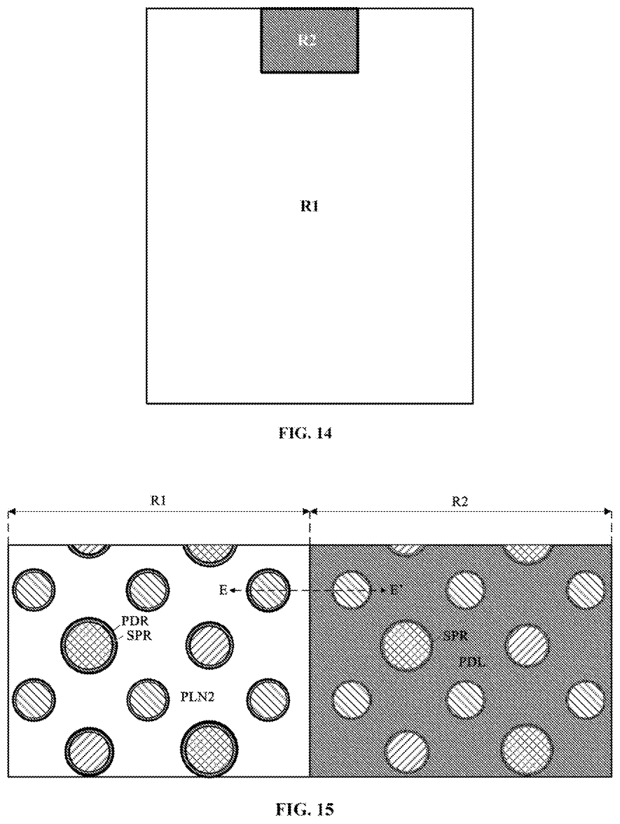

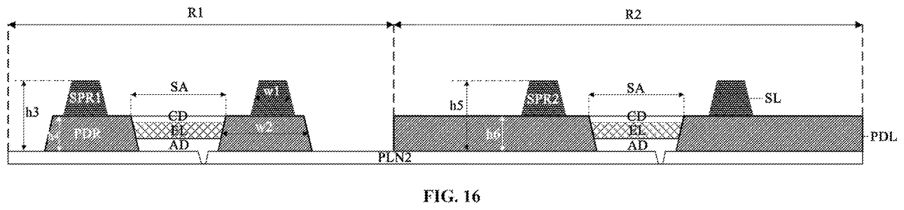

FIG. 14 is a schematic diagram illustrating the structure of a display substrate in some embodiments according to the present disclosure. FIG. 15 is a schematic diagram illustrating the structure of a first region and a second region of a display substrate in some embodiments according to the present disclosure. FIG. 16 is a cross-sectional view along a E-E′ line in FIG. 15. Referring to FIG. 14 to FIG. 16, the display substrate in some embodiments includes a first region R1 and a second region R2. In some embodiments, the display substrate in the first region R1 has a first visible light transmission rate, and in the second region R2 has a second visible light transmission rate. Optionally, the first visible light transmission rate is higher than the second visible light transmission rate. Optionally, the first visible light transmission rate is higher than the second visible light transmission rate by at least 10%, e.g., by at least 20%, by at least 30%, by at least 40%, by at least 50%, by at least 60%, by at least 70%, by at least 80%, by at least 90%, by at least 100%, by at least 150%, by at least 200%, by at least 250%, by at least 300%, by at least 350%, by at least 400%, by at least 450%, or by at least 500%. In one example, the first region R1 is a region where the display substrate is configured to display an augmented reality image.

In some embodiment, in the first region R1, the pixel definition layer PDL includes a plurality of pixel definition rings PDR, and the support layer SL includes a plurality of first support structures SPR1. In some embodiments, an orthographic projection of a respective pixel definition ring of the plurality of pixel definition rings PDR on a base substrate (e.g., the second planarization layer PLN2) at least partially overlaps with an orthographic projection of a respective first support structure of the plurality of first support structures SPR1 on the base substrate. Optionally, the orthographic projection of the respective pixel definition ring on the base substrate covers the orthographic projection of the respective first support structure on a base substrate. Optionally, the respective first support structure is in direct contact with the respective pixel definition ring.

In some embodiment, in the first region R1, a respective pixel definition ring of the plurality of pixel definition rings PDR defines a respective subpixel aperture of a plurality of subpixel apertures SA. In some embodiments, the respective pixel definition ring substantially surrounds at least a portion of the light emitting layer EL. A respective first support structure of the plurality of first support structures SPR1 at least partially (e.g., completely) surrounds the respective subpixel aperture of the plurality of subpixel apertures SA.

In some embodiment, in the second region R2, the plurality of pixel definition rings are absent. In the second region R2, the pixel definition layer PDL is a unitary structure continuously extending in the region, except that the pixel definition layer PDL does not extend into multiple subpixel apertures of the plurality of subpixel apertures SA in the second region R2. In the second region R2, the support layer SL includes a plurality of second support structures SPR2. A respective second support structure of the plurality of second support structures SPR2 at least partially (e.g., completely) surrounds the respective subpixel aperture of the plurality of subpixel apertures SA.

In some embodiment, in the first region R1, the respective first support structure of the plurality of first support structures SPR1 has a third height h3 relative to a base substrate (e.g., the second planarization layer PLN2) of the display substrate. The respective pixel definition ring of the plurality of pixel definition rings PDR has a fourth height h4 relative to the base substrate. By having the respective first support structure stacked on the respective pixel definition ring, the third height h3 is greater than the fourth height h4. When a mask plate is placed on the respective first support structure in the process of depositing, e.g., a light emitting material, the respective first support structure spaces apart the mask plate and other components of the display substrate, avoiding damages such as scratching and electrostatic discharge. In one example, the third height h3 is 2.7 μm, and the fourth height h4 is 1.5 μm. In one example, the respective first support structure has a thickness in a range of 0.6 μm to 1.2 μm, e.g., 0.6 μm to 0.8 μm, 0.8 μm to 1.0 μm, or 1.0 μm to 1.2 μm.

In some embodiment, in the second region R2, the respective second support structure of the plurality of second support structures SPR2 has a fifth height h5 relative to a base substrate (e.g., the second planarization layer PLN2) of the display substrate. The pixel definition layer PDL has a sixth height h6 relative to the base substrate. As shown in FIG. 13, by having the respective second support structure stacked on the pixel definition layer PDL, the fifth height h5 is greater than the sixth height h6. When a mask plate is placed on the respective second support structure in the process of depositing, e.g., a light emitting material, the respective second support structure spaces apart the mask plate and other components of the display substrate, avoiding damages such as scratching and electrostatic discharge. In one example, the fifth height h5 is 2.7 μm, and the sixth height h6 is 1.5 μm. In one example, the respective second support structure has a thickness in a range of 0.6 μm to 1.2 μm, e.g., 0.6 μm to 0.8 μm, 0.8 μm to 1.0 μm, or 1.0 μm to 1.2 μm.

In some embodiments, the third height h3 is substantially the same as the fifth height h5. In some embodiments, the fourth height h4 is substantially the same as the sixth height h6.

In the first region R1, in a cross-section perpendicular to a surface of the base substrate (e.g., the second planarization layer PLN2) and intersecting two adjacent first support structures of the plurality of first support structures SPR1, the respective first support structure has a shape having a first side closer to the base substrate and a second side on a side of the first side away from the base substrate, the first side having a width greater than the second side. Optionally, the respective first support structure in the cross-section has a trapezoidal shape.

In the second region R2, in a cross-section perpendicular to a surface of the base substrate (e.g., the second planarization layer PLN2) and intersecting two adjacent second support structures of the plurality of second support structures SPR2, the respective second support structure has a shape having a first side closer to the base substrate and a second side on a side of the first side away from the base substrate, the first side having a width greater than the second side. Optionally, the respective second support structure in the cross-section has a trapezoidal shape.

In the first region R1, in a cross-section perpendicular to a surface of the base substrate (e.g., the second planarization layer PLN2) and intersecting two adjacent first support structures of the plurality of first support structures SPR1, the respective pixel definition ring has a shape having a third side closer to the base substrate and a fourth side on a side of the third side away from the base substrate, the third side having a width greater than the fourth side. Optionally, the respective pixel definition ring in the cross-section has a trapezoidal shape.

In some embodiments, in a cross-section perpendicular to a surface of the base substrate (e.g., the second planarization layer PLN2) and intersecting two adjacent first support structures of the plurality of first support structures SPR1, the respective first support structure has a first average width w1, the respective pixel definition ring has a second average width w2. Optionally, w2 is greater than w1. Optionally, w2 is greater than w1 by at least 10%, e.g., by at least 20%, by at least 30%, by at least 40%, by at least 50%, by at least 60%, by at least 70%, by at least 80%, by at least 90%, by at least 100%, by at least 150%, by at least 200%, by at least 250%, by at least 300%, by at least 350%, by at least 400%, by at least 450%, or by at least 500%.

In some embodiments, in the first region R1, the respective first support structure is on a side of the respective pixel definition ring away from the base substrate. Optionally, the respective first support structure is in direct contact with the respective pixel definition ring. The display substrate includes a stacked structure comprising the respective first support structure and the respective pixel definition ring.

In some embodiments, in the second region R2, the respective second support structure is on a side of the pixel definition layer PDL away from the base substrate. Optionally, the respective second support structure is in direct contact with the pixel definition layer PDL. In some embodiments, the pixel definition layer PDL includes a black material. In some embodiments, the support layer SL includes a substantially transparent material.

In the present disclosure, the respective pixel definition ring may have various appropriate shapes. Examples of appropriate shapes of the respective pixel definition ring include a circular ring shape (see, e.g., FIG. 8), an ellipse ring shape, a polygonal ring shape such as a rectangular ring shape (see, e.g., FIG. 7B), a triangular ring shape, and a hexagonal ring shape. In one example, the respective pixel definition ring is a closed ring.

In the present disclosure, the respective support structure (including the respective first support structure and the respective second support structure) may have various appropriate shapes. Examples of appropriate shapes of the respective support structure include a circular ring shape (see, e.g., FIG. 12), an ellipse ring shape, a polygonal ring shape such as a rectangular ring shape (see, e.g., FIG. 7C), a triangular ring shape, and a hexagonal ring shape. In one example, the respective support structure is a closed ring.

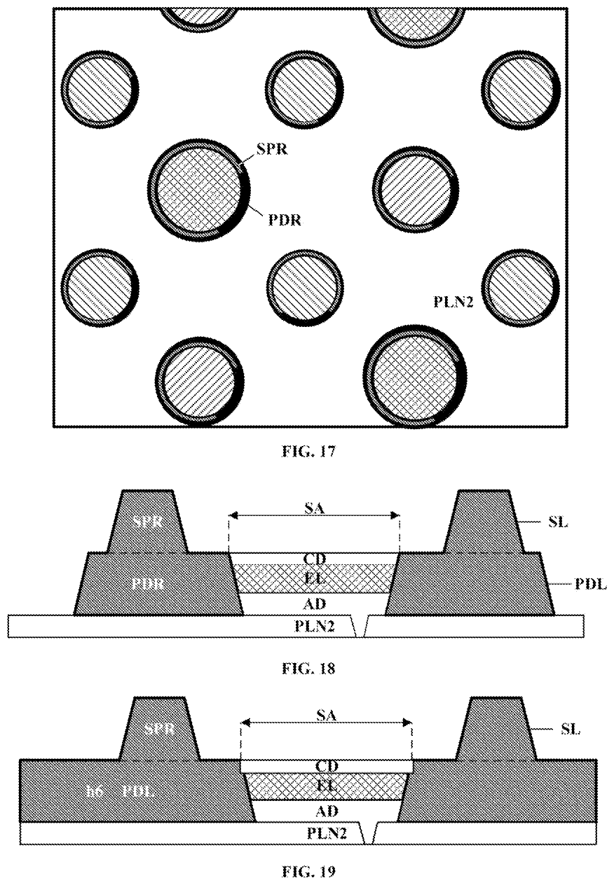

FIG. 17 is a schematic diagram illustrating the structure of a display substrate in some embodiments according to the present disclosure. Referring to FIG. 17, the respective support structure in some embodiment is an open ring comprising a gap in the ring shape.

In FIG. 9, the respective support structure and the respective pixel definition ring are two structures formed separately. FIG. 18 is a cross-sectional view in a display substrate in some embodiments according to the present disclosure. Referring to FIG. 18, in some embodiments, the respective support structure and the respective pixel definition ring are parts of a unitary structure. Optionally, the respective support structure and the respective pixel definition ring may be formed using a half-tone patterning process. Optionally, the respective support structure and the respective pixel definition ring both include a black material.

In FIG. 13, the respective support structure and the pixel definition layer PDL are two structures formed separately. FIG. 19 is a cross-sectional view in a display substrate in some embodiments according to the present disclosure. Referring to FIG. 19, in some embodiments, the respective support structure and the pixel definition layer PDL are parts of a unitary structure. Optionally, the respective support structure and the pixel definition layer PDL may be formed using a half-tone patterning process. Optionally, the respective support structure and the pixel definition layer PDL both include a black material.

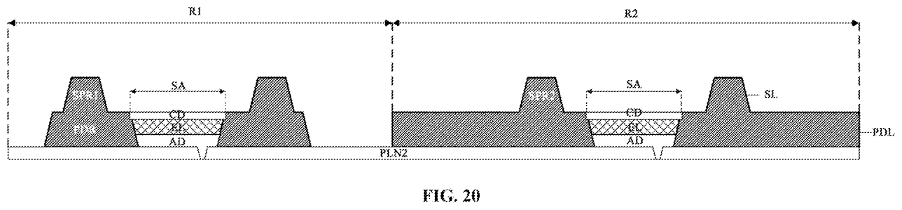

In FIG. 16, in the first region R1, the respective support structure and the respective pixel definition ring are two structures formed separately; in the second region R2, the respective support structure and the pixel definition layer PDL are two structures formed separately. FIG. 20 is a cross-sectional view in a display substrate in some embodiments according to the present disclosure. Referring to FIG. 20, in the first region R1, the first respective support structure and the respective pixel definition ring are parts of a unitary structure; in the second region R2, the second respective support structure and the pixel definition layer PDL are parts of a unitary structure. Optionally, the first respective support structure and the respective pixel definition ring in the first region R1 may be formed using a half-tone patterning process; and the second respective support structure and the pixel definition layer PDL in the second region R2 may be formed using a half-tone patterning process. Optionally, the first respective support structure, the second respective support structure, the pixel definition layer PDL (including the respective pixel definition ring) all include a black material.

Referring to FIG. 6, in some embodiments, the plurality of support structures SPR are spaced apart from each other by the encapsulating layer EN. Specifically, the encapsulating layer EN at least partially fills in a space between adjacent support structures of the plurality of support structures SPR. Optionally, the plurality of pixel definition rings PDR are spaced apart from each other by the encapsulating layer EN. Specifically, the encapsulating layer EN at least partially fills in a space between pixel definition rings of the plurality of pixel definition rings PDR. The first inorganic encapsulating sub-layer CVD1 has a substantially uniform thickness. However, the organic encapsulating sub-layer IJP has a non-uniform thickness in different regions of the display substrate. In some embodiments, the organic encapsulating sub-layer IJP has a first thickness t1 in a first sub-region U1, a second thickness t2 in a second sub-region U2, and a third thickness 13 in a third sub-region U3. The first sub-region is in the inter-subpixel region, is between adjacent support structures of the plurality of support structures SPR, and the support layer SL and the pixel definition layer PDL is absent in the first sub-region U1. The second sub-region U2 is in a respective subpixel region of the plurality of subpixel regions SR, and the support layer SL and the pixel definition layer PDL is absent in the second sub-region U2. Optionally, the light emitting layer EL is present in the second sub-region U2. The third sub-region U3 is in the inter-subpixel region, and both the respective support structure and the respective pixel definition ring are present in the third sub-region U3. In some embodiments, the first thickness t1 is greater than the second thickness t2, and the second thickness t2 is greater than the third thickness t3.

In some embodiment, the organic encapsulating sub-layer IJP has a fourth thickness t4 in a fourth sub-region U4. The fourth sub-region U4 is a sub-region wherein the respective support structure is absent and the respective pixel definition ring is present. In some embodiments, the first thickness t1 is greater than the second thickness t2, the second thickness t2 is greater than the fourth thickness 14, and the fourth thickness t4 is greater than the third thickness t3.

In some embodiments, the second planarization layer PLN2 is in direct contact with the pixel definition layer PDL, the anode AD, and the one or more common layers CL in the first sub-region U1. Optionally, the second planarization layer PLN2 is in direct contact with the pixel definition layer PDL, the anode AD, and an organic material layer in the first sub-region U1. Optionally, the second planarization layer PLN2 is in direct contact with the pixel definition layer PDL, the anode AD, and a cathode layer in the first sub-region U1.

In another aspect, the present disclosure provides a display apparatus including the display substrate described herein or fabricated by a method described herein, and one or more integrated circuits connected to the display substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a mini light emitting diode display apparatus. Optionally, the display apparatus is a quantum dots light emitting diode display apparatus.

In another aspect, the present disclosure provides a method of fabricating a display substrate. In some embodiments, the method includes forming a pixel definition layer on a base substrate, the pixel definition layer defining a plurality of subpixel apertures, a respective subpixel aperture of the plurality of subpixel apertures configured to receive at least a portion of a light emitting layer; and forming a support layer on a side of the pixel definition layer away from the base substrate. Optionally, forming the support layer includes forming a plurality of support structures. Optionally, a respective support structure of the plurality of support structures at least partially surrounds the respective subpixel aperture.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A display substrate, comprising:
a base substrate;
a pixel definition layer defining a plurality of subpixel apertures, a respective subpixel aperture of the plurality of subpixel apertures configured to receive at least a portion of a light emitting layer; and
a support layer on a side of the pixel definition layer away from the base substrate;
wherein the support layer comprises a plurality of support structures; and
a respective support structure of the plurality of support structures at least partially surrounds the respective subpixel aperture.

2. The display substrate of claim 1, wherein the pixel definition layer comprises a plurality of pixel definition rings; and
an orthographic projection of a respective pixel definition ring of the plurality of pixel definition rings on the base substrate covers an orthographic projection of the respective support structure on the base substrate.

3. The display substrate of claim 2, wherein the plurality of pixel definition rings are spaced apart from each other.

4. The display substrate of claim 2, wherein the respective support structure is in direct contact with the respective pixel definition ring.

5. The display substrate of claim 2, wherein, in a cross-section perpendicular to a surface of the base substrate and intersecting two adjacent support structures of the plurality of support structure, the respective support structure has a first average width, the respective pixel definition ring has a second average width; and
the second average width is greater than the first average width.

6. The display substrate of claim 2, wherein the respective pixel definition ring has a first side and a second side substantially opposite to each other, a third side connecting the first side and the second side, and a fourth side connecting the first side and the second side;
the second side is on a side of the first side distal to the base substrate;
the fourth side is on a side of the third side away from a center of the respective pixel definition ring;
the third side has a first slope angle with respect to the first side;
the fourth side has a second slope angle with respect to the first side;
the first slope angle is in a range of 15 degrees to 45 degrees; and
the second slope angle is in a range of 15 degrees to 45 degrees.

7. The display substrate of claim 1, wherein the pixel definition layer comprises a black material; and
the support layer and the pixel definition layer comprise different materials.

8. The display substrate of claim 1, wherein, in at least a region of the display substrate, a portion of the pixel definition layer is a unitary structure defining the plurality of subpixel apertures.

9. The display substrate of claim 7, wherein the plurality of support structures in the region and outside the region are made of a same material; and
the unitary structure in the region and a plurality of pixel definition rings outside the region are made of a same material.

10. The display substrate of claim 1, wherein the plurality of support structures are spaced apart from each other at least partially by an encapsulating layer.

11. The display substrate of claim 1, comprising a first region and a second region;
wherein the display substrate in the first region has a first visible light transmission rate, and in the second region has a second visible light transmission rate; and
the first visible light transmission rate is higher than the second visible light transmission rate.

12. The display substrate of claim 10, wherein, in the first region, the pixel definition layer comprises a plurality of pixel definition rings, and the support layer comprises a plurality of first support structures;
in the first region, an orthographic projection of a respective pixel definition ring of the plurality of pixel definition rings on the base substrate at least partially overlaps with an orthographic projection of a respective first support structure of the plurality of first support structures on the base substrate;
in the second region, a portion of the pixel definition layer is a unitary structure continuously extending in the region, except that the pixel definition layer does not extend into the plurality of subpixel apertures;
in the second region, the support layer comprises a plurality of second support structures; and
in the second region, an orthographic projection of the portion of the pixel definition layer on the base substrate at least partially overlaps with an orthographic projection of the respective second support structure on the base substrate.

13. The display substrate of claim 1, wherein the respective support structure is a closed ring.

14. The display substrate of claim 1, wherein the respective support structure is an open ring.

15. The display substrate of claim 2, wherein the respective support structure and the respective pixel definition ring are parts of a unitary structure.

16. The display substrate of claim 1, wherein the pixel definition layer comprises a black material; and
the support layer comprises the black material.

17. A display apparatus, comprising the display substrate of claim 1, and one or more integrated circuits connected to the display substrate.

18. A display substrate, comprising:
a base substrate;
a pixel definition layer defining a plurality of subpixel apertures, a respective subpixel aperture of the plurality of subpixel apertures configured to receive at least a portion of a light emitting layer;
a support layer on a side of the pixel definition layer away from the base substrate; and
an encapsulating layer on a side of the support layer away from the base substrate;
wherein the support layer comprises a plurality of support structures;
the encapsulating layer comprises a first inorganic encapsulating sub-layer, an organic encapsulating sub-layer on the first inorganic encapsulating sub-layer, and a second inorganic encapsulating sub-layer on a side of the organic encapsulating sub-layer away from the first inorganic encapsulating sub-layer;
the organic encapsulating sub-layer has a first thickness in a first sub-region, a second thickness in a second sub-region, and a third thickness in a third sub-region; and
the first thickness, the second thickness, and the third thickness are different from each other.

19. The display substrate of claim 18, wherein the first sub-region is in an inter-subpixel region, is between adjacent support structures of the plurality of support structures;
the support layer and the pixel definition layer is absent in the first sub-region;
the second sub-region is in a respective subpixel region of a plurality of subpixel regions;
the support layer and the pixel definition layer is absent in the second sub-region;
the light emitting layer is present in the second sub-region;
the third sub-region is in the inter-subpixel region;
the respective support structure and the respective pixel definition ring are both present in the third sub-region; and
the first thickness is greater than the second thickness, and the second thickness is greater than the third thickness.

20. The display substrate of claim 19, wherein the organic encapsulating sub-layer has a fourth thickness in a fourth sub-region;
the fourth sub-region is a sub-region wherein the respective support structure is absent and the pixel definition layer is present; and
the second thickness is greater than the fourth thickness, and the fourth thickness is greater than the third thickness.
